(19) United States
(12) Patent Application Publication
(10) Pub. No.: US 2011/0143049 A1
(43) Pub. Date: Jun. 16, 2011

(54) LUBRICANT REMOVAL TO REUSE DISKS FOR CONDITIONING DEPOSITION TOOLS

(76) Inventors: Xing-Cai Guo, Tracy, CA (US); Kanaiyalal C. Patel, Fremont, CA (US); Daryl J. Pocker, San Jose, CA (US); Kurt A. Rubin, San Jose, CA (US)

(21) Appl. No.: 12/639,817

(22) Filed: Dec. 16, 2009

(51) Int. Cl. B05D 3/06; C23C 14/02; C25F 1/00

(52) U.S. Cl. 427/534; 427/129; 204/192.32

(57) ABSTRACT

A disk that is identified as defective in a manufacturing process is reused for conditioning a deposition tool that deposits a magnetic material onto disks. After the disk has been identified as defective, a surface of the disk is cleaned in a cleaning tool to remove a lubricant material using a dry etch process. The cleaned disk is moved from the cleaning tool into the deposition tool. The deposition tool is conditioned by depositing the magnetic material onto the cleaned surface of the disk. Because the disk has been cleaned, reusing the defective disk to condition the deposition tool does not contaminate the deposition tool.

### BACKGROUND

1. Field of the Invention

The invention is related to the field of disks and, in particular, to cleaning a disk and/or to condition deposition tools that form magnetic disks.

2. Statement of the Problem

A hard disk drive can include one or more disks each having a magnetic material for recording information magnetically. Each disk is manufactured by depositing the magnetic material onto the disk using a deposition tool that may use a sputtering process. A lubricant material is then applied on the disk to reduce wear as a read/write head flies on top of the disk for an extended period of time. The disk is subsequently tested to identify manufacturing defects and may be discarded if the disk does not pass the test.

Before stable production of disks can begin, the deposition tool is conditioned. The deposition tool is “conditioned” after the deposition tool has been exercised by depositing the magnetic material onto a number of “dummy” disks. The “dummy” disks are free of contaminants (for example, the lubricant material) that may contaminate the deposition tool. Although a “dummy” disk is otherwise just like a regular disk, the “dummy” disk is not tested as a finished product. Rather, the “dummy” disk is discarded after too much magnetic material has been deposited onto the “dummy” disk as a result of conditioning the deposition tool. Thus, disk manufacturers incur significant costs in buying “dummy” disks simply to condition deposition tools.

### SUMMARY

Embodiments described herein provide methods to clean a lubricant material off a disk that has been identified as defective. Rather than buying “dummy” disks, disk manufacturers can clean the lubricant material off the defective disks and reuse the clean disks as “dummy” disks to condition deposition tools.

One embodiment is a method for conditioning a deposition tool. The method includes identifying a disk as defective after a lubricant material has been applied on a surface of the disk. The method also includes moving the disk into a cleaning tool, and cleaning the disk in the cleaning tool to remove the lubricant material from the surface using a dry etch process. Additionally, the method includes moving the disk into the deposition tool, and depositing a magnetic material onto the cleaned surface of the disk in the deposition tool to condition the deposition tool.

Another embodiment is a method for cleaning the lubricant material from the disk using a dry etch process. The method includes introducing a noble gas into the cleaning tool, and creating a plasma from the noble gas. The method further includes sputtering ions from the plasma onto a surface of the disk for less than two seconds to dislodge the lubricant material.

Other exemplary embodiments may be described below.

### DESCRIPTION OF THE DRAWINGS

Some embodiments of the present invention are now described, by way of example only, and with reference to the accompanying drawings. The same reference number represents the same element or the same type of element on all drawings.

FIG. 1 illustrates a block diagram of manufacturing disks in an exemplary embodiment.

FIG. 2 is a flow chart illustrating a method of conditioning a deposition tool in an exemplary embodiment.

FIG. 3 illustrates a block diagram of a deposition tool and a cleaning tool to reuse a disk in an exemplary embodiment.

FIG. 4 is a flow chart illustrating a method of cleaning a lubricant material from a disk in an exemplary embodiment.

### DESCRIPTION OF EMBODIMENTS

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention, and are to be construed as being without limitation to such specifically recited examples and conditions. As a result, the invention is not limited to the specific embodiments or examples described below, but by the claims and their equivalents.

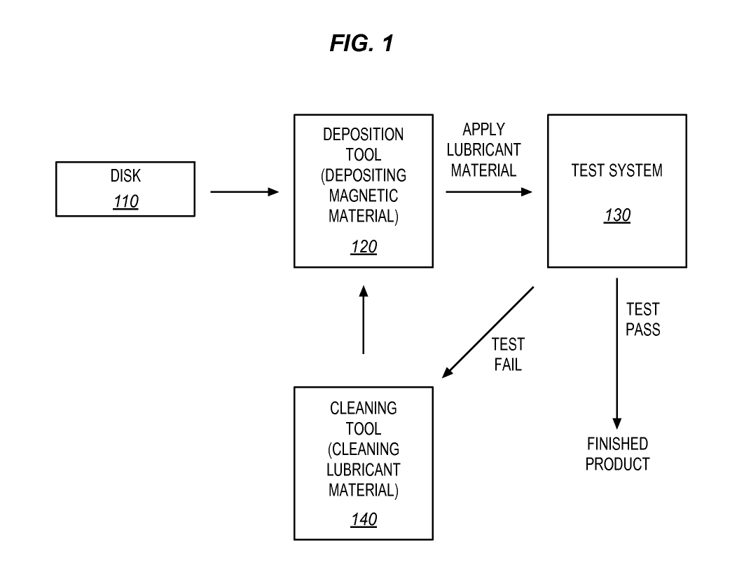

FIG. 1 illustrates a block diagram of manufacturing disks in an exemplary embodiment. A disk 110 may be any disk having a suitable substrate that is to be manufactured for mounting into a hard disk drive. For example, the suitable substrate may comprise a glass and/or aluminum and/or aluminum alloy substrate. The disk 110 may be manufactured for perpendicular recording or longitudinal recording. The disk 110 may also be manufactured to comprise a non-patterned (conventional) disk or a patterned disk (for example, discrete track media and/or bit-patterned media). The disk 110 is moved into a deposition tool 120 for the deposition tool 120 to deposit a magnetic material onto the disk 110. For example, the deposition tool 120 may comprise a sputtering tool that sputters the magnetic material for the magnetic material to be deposited onto the disk 110.

A lubricant material is then applied on the disk 110. For example, the disk may be dipped in a bath containing the lubricant material. The lubricant material may comprise a fluorinated lubricant including a perfluoropolyether (PFPE) lubricant. A thickness of the lubricant material on a non-patterned disk may be from 0.5 to 1.5 nm inclusive. Conversely, a patterned disk has areas etched away from the surface, and a thickness of the lubricant material on the patterned disk may be from 0.5 to 25 nm inclusive because the lubricant material may fill deep grooves on the patterned disk. Subsequently, the disk 110 is moved to a test system 130 for the test system 130 to identify if the disk 110 is defective by running a test. For example, the test system 130 may comprise a glide test system, which includes a glide test head to generate a test signal to run a glide test for evaluating the disk 110. If the disk 110 passes the test, then the disk may be considered a finished product.

However, if the disk 110 fails the test, the disk 110 may be reused to condition the deposition tool 120 rather than discarding the disk 110. To reuse the disk 110, the disk 110 may be cleaned in a cleaning tool 140 to remove the lubricant material and then used to condition the deposition tool 120. The cleaning tool 140 may comprise any tool that is operable to clean the lubricant material off the disk 110. For example, the cleaning tool 140 may comprise a tool or system that implements a dry etch process.

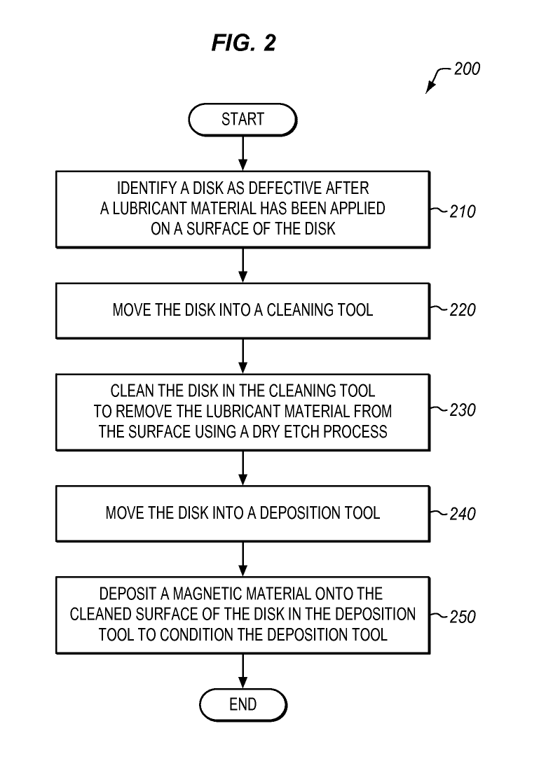

FIG. 2 is a flow chart illustrating a method 200 of conditioning the deposition tool 120 in an exemplary embodiment. The steps of this method will be described with reference to FIG. 1, but those skilled in the art will appreciate that the method 200 may be performed in other systems. Also, the steps of the flow charts described herein are not all inclusive and may include other steps not shown, and the steps may be performed in an alternative order.

At step 210, the test system 130 identifies the disk 110 as defective after a lubricant material has been applied on a surface of the disk 110. For example, the disk 110 may have already been manufactured by depositing the magnetic material on the disk 110, and then dipping the disk 110 in the bath containing the lubricant material. Subsequently, the test system 130 tests the disk 110. The test system 130 may identify the disk 110 as “defective” if the disk 110 fails a test (for example, the glide test) at the test system 130.

In some embodiments, the test system 130 may identify the disk 110 as defective without actually testing the disk 110. For example, the test system 130 may identify other sample disks in a batch of disks as defective. If the defect rate is sufficiently high, the test system 130 may identify the disk 110 in the same batch of disks as defective because the disk 110 is likely to be defective as well. In another embodiment, the step 210 may be optional and the disk 110 is moved into the cleaning tool 140 without the disk 110 being identified as defective. For example, an excess number of disks may be manufactured. Rather than mounting these excess disks into final products, these disks may be cleaned and reused without identifying them as defective.

Instead of discarding the disk 110 after identifying it as defective, the disk 110 is moved from the test system 130 into the cleaning tool 140 at step 220. For example, moving the disk 110 into the cleaning tool 140 may be performed by a robot and/or a conveyor system. Besides automating movements of the disk 110, the overall manufacturing system may also be automated so that those disks that have been identified as defective are cleaned to be reused by automatically proceeding from step 210 to step 220.

At step 230, the cleaning tool 140 cleans the disk 110 to remove the lubricant material from the surface of the disk 110 using a dry etch process. The dry etch process may last less than 10 seconds in an embodiment. Thus, the cleaning process causes little delay and is well suited in an efficient manufacturing process.

Other methods may be used to clean the disk 110, but are not as effective. For example, strong liquid based etchants (for example, sulfuric acid and hydrogen peroxide) are not effective at cleaning the lubricant material off the disk 110. Not only are these etchants not effective, they cause corrosion to the disk 110. Alternatively, baking the disk in an oven at high temperatures for five minutes does burn off the lubricant material. However, baking the disk 110 at high temperatures causes the disk 110 to become damaged. Five minutes is also much too long in an efficient manufacturing process. Not all of the lubricant will evaporate by baking the disk 110 at intermediate temperatures.

At step 240, the disk 110 is moved from the cleaning tool 140 into the deposition tool 120, which may be performed by a robot and/or a conveyor system. At step 250, the deposition tool 120 deposits a magnetic material onto the cleaned surface of the disk 110 in the deposition tool 120 to condition the deposition tool 120. The deposition tool 120 is “conditioned” after the deposition tool 120 has been exercised by depositing the magnetic material onto a number of disks. The deposition tool 120 is then ready for stable production.

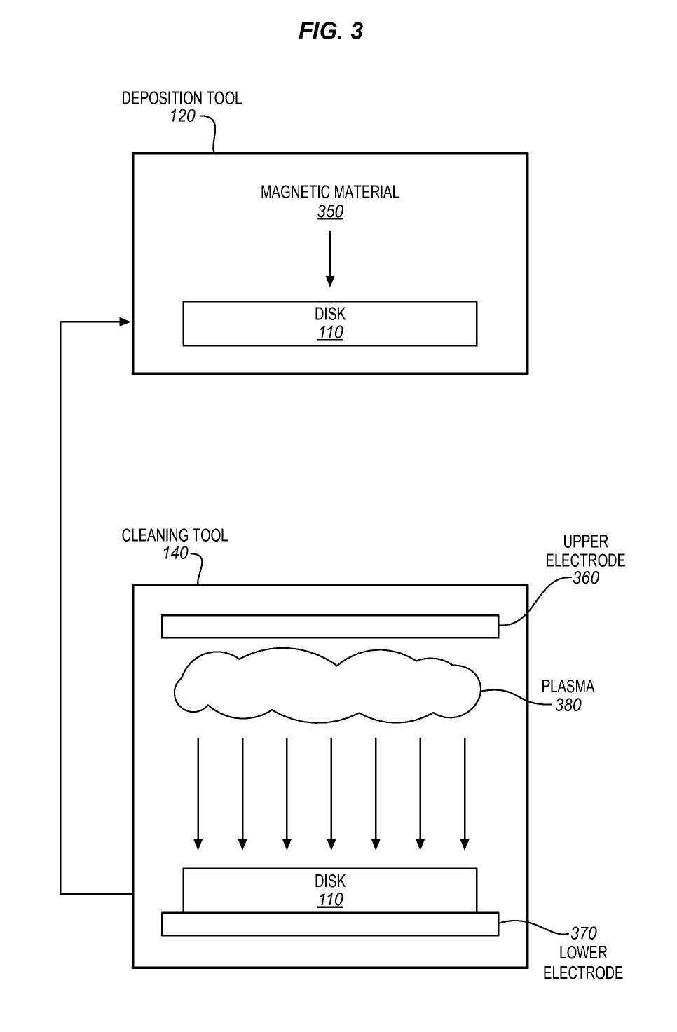

FIG. 3 illustrates a block diagram of the deposition tool 120 and a cleaning tool 140 to reuse the disk 110 in an exemplary embodiment. The cleaning tool 140 comprises an upper electrode 360 and a lower electrode 370 in a chamber. The cleaning tool 140 also comprises a power source for creating plasma 380. The deposition tool 120 deposits a magnetic material 350 onto the disk 110.

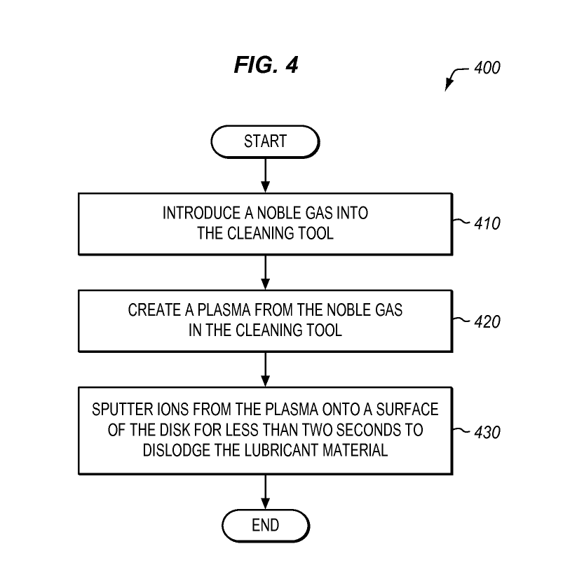

FIG. 4 is a flow chart illustrating a method 400 of cleaning a lubricant material from a disk in an exemplary embodiment. The steps of this method will be described with reference to FIGS. 1 and 2, but those skilled in the art will appreciate that the method 400 may be performed in other systems. It is assumed that the disk 110 has failed the test at the test system 130, but the disk 110 can still be reused for conditioning the deposition tool 120 if the disk 110 is clean and free of contaminants (for example, the lubricant material). Thus, the disk 110 is moved into the cleaning tool 140.

At step 410, a noble gas is introduced into the cleaning tool 140 (typically automatically by the cleaning tool 140). For example, the noble gas may comprise at least one of Argon, Krypton, and Neon in one embodiment. The noble gas may have a gas pressure of about 30 milliTorr. In various embodiments, the gas pressure may be greater than 2 milliTorr, less than 40 milliTorr, less than 60 milliTorr, between 2 and 60 milliTorr, between 2 and 40 milliTorr, or from 3 to 30 milliTorr inclusive.

At step 420, the cleaning tool 140 creates the plasma 380 from the noble gas in the cleaning tool 140. For example, the cleaning tool 140 may create a strong radio frequency electrical field, for example, at a frequency of 13.56 megahertz and at a few hundred watts. The resulting oscillating field ionizes gas molecules by stripping them of electrons to create the plasma 380 that has a higher concentration of positive gas ions.

At step 430, the cleaning tool 140 sputters ions from the plasma 380 on to a surface of the disk 110 for less than 10 seconds to dislodge the lubricant material. For example, electrons move up and down the chamber as the plasma 380 is created. The lower electrode 370 is isolated from the rest of the chamber and holds the disk 110, while the upper electrode 360 is grounded. Because the lower electrode 370 is isolated from the rest of the chamber, charges build up on the lower electrode 370 but not on the upper electrode 360. The voltage difference between the two electrodes then causes the positive gas ions from the plasma 380 to collide onto the disk 110 to dislodge the lubricant material, thus cleaning the disk 110.

This dry etch process (the process of sputtering ions from the plasma 380) may last about 1 second in one embodiment when the gas pressure is about 30 milliTorr. Although vacuuming off air and material in the cleaning tool 140 reduces the chance that the dislodged lubricant material would be deposited back onto the disk 110, contamination (of the cleaning tool 140 and/or the disk 110) can still happen if the dry etch process lasts too long. Typically, shorter durations correspond with higher gas pressures, and longer durations correspond with lower gas pressures. In various embodiments, the dry etch process may last more than 0.5 seconds, less than 10 seconds, between 0.5 and 10 seconds, between 0.5 and 6 seconds, or from 1 to 5 seconds inclusive.

The cleaned disk 110 may then be moved into the deposition tool 120 for conditioning the deposition tool 120. The deposition tool 120 may sputter a target containing a magnetic material 350 for the magnetic material 350 to be deposited onto the cleaned disk 110. In one embodiment, depositing the magnetic material forms a thin film magnetic layer on the disk 110. Although the disk 110 is still discarded after having been used for conditioning the deposition tool 120 a number of times, the manufacturer does not need to purchase regular disks only to use them as “dummy” disk for conditioning the deposition tool 120. After the deposition tool 120 has been conditioned, stable production of disks can begin. Some of the manufactured disks may also be identified as defective by the test system 130 just like the disk 110, and the newly identified defective disks may also be cleaned and reused to condition the deposition tool 120 or another deposition tool. Consequently, depositing the magnetic material may form another thin film magnetic layer on the disk 110.

It is noted that a number of magnetic materials may be deposited onto the disk 110 in layers (for example, forming a number of thin film magnetic layers) using a number of deposition tools. The disk 110 may also be deposited with a top coat (which may be a thin film magnetic layer) before being applied with the lubricant material in some embodiments. Thus, if the disk 110 is identified as defective, the lubricant material may be cleaned off the top coat, and the disk 110 may be reused for conditioning the deposition tool 120 by having the deposition tool 120 depositing a magnetic material or another top coat on top of the existing top coat. Consequently, the disk 110 may have two layers of top coats next to each other, or may have a magnetic layer right on top of the existing top coat. Because the disk 100 may be reused for conditioning the deposition tool 120 again (and may also be reused repeatedly), the disk may have three or more layers of top coat next to each other, or may have multiple magnetic layers on top of the existing top coat.

Alternatively or in addition, following the dry etch process, a pattern may be created on the cleaned disk to create a patterned disk. For example, creating the pattern may include applying a resist layer (i.e., an imprint resist in a nanoimprint lithography method) on the cleaned surface of the disk, pressing a stamper having the pattern against the resist layer on the surface of the disk, and etching the disk to transfer the pattern onto the surface of the disk.

Although specific embodiments were described herein, the scope of the invention is not limited to those specific embodiments. The scope of the invention is defined by the following claims and any equivalents thereof.

We claim:

1. A method for conditioning a deposition tool, the method comprising:
identifying a disk as defective after a lubricant material has been applied on a surface of the disk;
moving the disk into a cleaning tool;
cleaning the disk in the cleaning tool to remove the lubricant material from the surface using a dry etch process;
moving the disk into the deposition tool; and
depositing a magnetic material onto the cleaned surface of the disk in the deposition tool to condition the deposition tool.

2. The method of claim 1, wherein cleaning the disk comprises sputtering ions from a plasma onto the surface of the disk for less than 10 seconds, wherein the plasma is created from a noble gas.

3. The method of claim 2, wherein the lubricant material comprises a fluorinated lubricant.

4. The method of claim 2, wherein the lubricant material comprises a perfluoropolyether (PFPE) lubricant.

5. The method of claim 2, wherein the noble gas comprises at least one of Argon, Krypton, and Neon.

6. The method of claim 2, wherein cleaning the disk comprises introducing the noble gas having a gas pressure greater than 2 milliTorr into the cleaning tool.

7. The method of claim 2, wherein the lubricant material comprises a perfluoropolyether (PFPE) lubricant, and wherein cleaning the disk comprises:
introducing the noble gas having a gas pressure between 2 and 40 milliTorr into the cleaning tool, wherein the noble gas comprises at least one of Argon, Krypton, and Neon;
creating a plasma from the noble gas in the cleaning tool; and
sputtering ions from the plasma onto the surface of the disk for between 0.5 and 6 seconds.

8. The method of claim 2, wherein the disk comprises one of a patterned disk with areas etched away from the surface of the patterned disk and a non-patterned disk, and wherein a thickness of the lubricant material on the patterned disk is from 0.5 to 25 nm inclusive, and wherein a thickness of the lubricant material on the non-patterned disk is from 0.5 to 1.5 nm inclusive.

9. The method of claim 1, further comprising:
depositing the magnetic material onto another disk in the deposition tool to manufacture the other disk, wherein depositing the magnetic material forms a thin film magnetic layer on the disk;
applying the lubricant material on the other disk;
identifying the other disk as defective;
cleaning the other disk in the cleaning tool to remove the lubricant material; and
depositing the magnetic material onto the other cleaned disk in the deposition tool to condition the deposition tool, wherein depositing the magnetic material forms another thin film magnetic layer on the disk.

10. A method for cleaning a lubricant material from a disk using a dry etch process, the method comprising:
introducing a noble gas into a cleaning tool;
creating a plasma from the noble gas in the cleaning tool; and
sputtering ions from the plasma onto a surface of the disk for less than 10 seconds to dislodge the lubricant material.

11. The method of claim 10, wherein the lubricant material comprises a fluorinated lubricant.

12. The method of claim 10, wherein the lubricant material comprises a perfluoropolyether (PFPE) lubricant.

13. The method of claim 10, wherein the noble gas comprises at least one of Argon, Krypton, and Neon.

14. The method of claim 10, wherein introducing the noble gas comprises introducing the noble gas having a gas pressure less than 60 milliTorr.

15. The method of claim 10, wherein:
the lubricant material comprises a perfluoropolyether (PFPE) lubricant;
the noble gas comprises at least one of Argon, Krypton, and Neon;
introducing the noble gas comprises introducing the noble gas having a gas pressure between 2 and 40 milliTorr into the cleaning tool; and
sputtering the ions of the noble gas comprises sputtering ions from the plasma onto the surface of the disk for between 0.5 second and 6 seconds.

16. The method of claim 10, further comprising:
creating a pattern on the cleaned surface of the disk.

17. The method of claim 16, wherein creating the pattern on the surface of the disk comprises:
applying a resist layer on the cleaned surface of the disk;
pressing a stamper having the pattern against the resist layer on the surface of the disk; and
etching the disk to transfer the pattern onto the surface of the disk.

18. A method for conditioning a deposition tool, the method comprising:
moving a disk into a cleaning tool, wherein a lubricant material has been applied on a surface of the disk, and wherein the lubricant material comprises a fluorinated lubricant;
introducing a noble gas having a gas pressure greater than 2 milliTorr into the cleaning tool;
creating a plasma from the noble gas in the cleaning tool;
sputtering ions from the plasma onto the surface of the disk for less than 10 seconds to clean the lubricant material from the surface of the disk;
moving the disk into a deposition tool; and
depositing a magnetic material onto the cleaned surface of the disk in the deposition tool to condition the deposition tool.

19. The method of claim 18, wherein the lubricant material comprises a perfluoropolyether (PFPE) lubricant, and wherein the noble gas comprises at least one of Argon, Krypton, and Neon.

20. The method of claim 18, wherein introducing the noble gas comprises introducing the noble gas having a gas pressure less than 40 milliTorr; and wherein sputtering the ions of the noble gas comprises sputtering ions from the plasma onto the surface of the disk for between 0.5 and 6 seconds.
